(19) United States
(12) Patent Application Publication
(10) Pub. No.: US 2017/0141046 A1
(43) Pub. Date: May 18, 2017

(54) SEMICONDUCTOR DEVICE WITH AN ELECTROMAGNETIC INTERFERENCE (EMI) SHIELD

(71) Applicant: Amkor Technology, Inc., Tempe, AZ (US)

(72) Inventors: Jin Suk Jeong, Seoul (KR); Kyeong Sool Seong, Seoul (KR); Kye Ryung Kim, Hwaseong-si (KR); Young Ik Kwon, Seoul (KR); Ki Dong Sim, Yongin-si (KR)

(21) Appl. No.: 15/149,378

(22) Filed: May 9, 2016

(30) Foreign Application Priority Data
Nov. 18, 2015 (KR) 10-2015-0162075

(51) Int. Cl. H01L 23/552; H01L 23/31; H01L 23/498; H01L 21/48; H01L 21/56

(52) U.S. Cl. CPC H01L 23/552; H01L 21/485; H01L 21/4853; H01L 21/565; H01L 23/49811; H01L 23/3114; H01L 2021/60022

(57) ABSTRACT

A method for forming a semiconductor device with an electromagnetic interference shield is disclosed and may include coupling a semiconductor die to a first surface of a substrate, encapsulating the semiconductor die and portions of the substrate using an encapsulant, placing the encapsulated substrate and semiconductor die on an adhesive tape, and forming an electromagnetic interference (EMI) shield layer on the encapsulant, on side surfaces of the substrate, and on portions of the adhesive tape adjacent to the encapsulated substrate and semiconductor die. The adhesive tape may be peeled away from the encapsulated substrate and semiconductor die, thereby leaving portions of the EMI shield layer on the encapsulant and on the side surfaces of the substrate with other portions of the EMI shield layer remaining on portions of the adhesive tape. Contacts may be formed on a second surface of the substrate opposite to the first surface of the substrate.

### CROSS REFERENCE TO RELATED APPLICATIONS

The present application makes reference to, claims priority to, and claims the benefit of Korean Patent Application No. 10-2015-0162075, filed on Nov. 18, 2015, the contents of which are hereby incorporated herein by reference, in their entirety.

### FIELD

Certain example embodiments of the disclosure relate to semiconductor chip packaging. More specifically, certain example embodiments of the disclosure relate to a semiconductor device with an electromagnetic interference (EMI) shield.

### BACKGROUND

While semiconductor packaging continues to trend towards miniaturization, semiconductor devices incorporated into the product are also required to have increased functionality and reduced size. In addition, in order to reduce size of a semiconductor device, the area and thickness of the semiconductor device need to be reduced.

Further limitations and disadvantages of conventional and traditional approaches will become apparent to one of skill in the art, through comparison of such systems with the present disclosure as set forth in the remainder of the present application with reference to the drawings.

### BRIEF SUMMARY

A semiconductor device with an electromagnetic interference (EMI) shield, substantially as shown in and/or described in connection with at least one of the figures, as set forth more completely in the claims.

Various advantages, aspects and novel features of the present disclosure, as well as details of various illustrated example supporting embodiments, will be more fully understood from the following description and drawings.

### BRIEF DESCRIPTION OF SEVERAL VIEWS OF THE DRAWINGS

FIGS. 1A and 1B are cross-sectional views illustrating semiconductor devices according to embodiments of the present disclosure.

FIGS. 2A to 2E are cross-sectional views sequentially illustrating a method of manufacturing a semiconductor device according to an embodiment of the present disclosure.

FIGS. 3A to 3D are cross-sectional views sequentially illustrating a method of manufacturing a semiconductor device according to another embodiment of the present disclosure.

### DETAILED DESCRIPTION

Certain aspects of the disclosure may be found in a semiconductor device with an electromagnetic interference (EMI) shield. Example aspects of the disclosure may comprise coupling a semiconductor die to a first surface of a substrate, encapsulating the semiconductor die and portions of the first surface of the substrate using an encapsulant, placing the encapsulated substrate and semiconductor die on an adhesive tape, and forming an electromagnetic interference (EMI) shield layer on the encapsulant, on side surfaces of the substrate, and on portions of the adhesive tape adjacent to the encapsulated substrate and semiconductor die. The adhesive tape may be peeled away from the encapsulated substrate and semiconductor die, thereby leaving portions of the EMI shield layer on the encapsulant and on the side surfaces of the substrate with other portions of the EMI shield layer remaining on portions of the adhesive tape that were adjacent to the encapsulated substrate and semiconductor die. Contacts may be formed on a second surface of the substrate opposite to the first surface of the substrate. The contacts may comprise conductive bumps or conductive lands. An adhesive layer may be placed on the contacts and the second surface of the substrate, such that the contacts are encapsulated by the adhesive layer. The adhesive layer may be removed in the peeling away of the adhesive tape. The EMI shield layer may comprise one or more of silver, copper, aluminum, nickel, palladium, and chromium. The EMI shield layer may be coupled to a ground circuit pattern of the substrate.

This disclosure provides supporting example embodiments. The scope of the present disclosure is not limited by these example embodiments. Numerous variations, whether explicitly provided for by the specification or implied by the specification, such as variations in structure, dimension, type of material and manufacturing process, may be implemented by one skilled in the art in view of this disclosure.

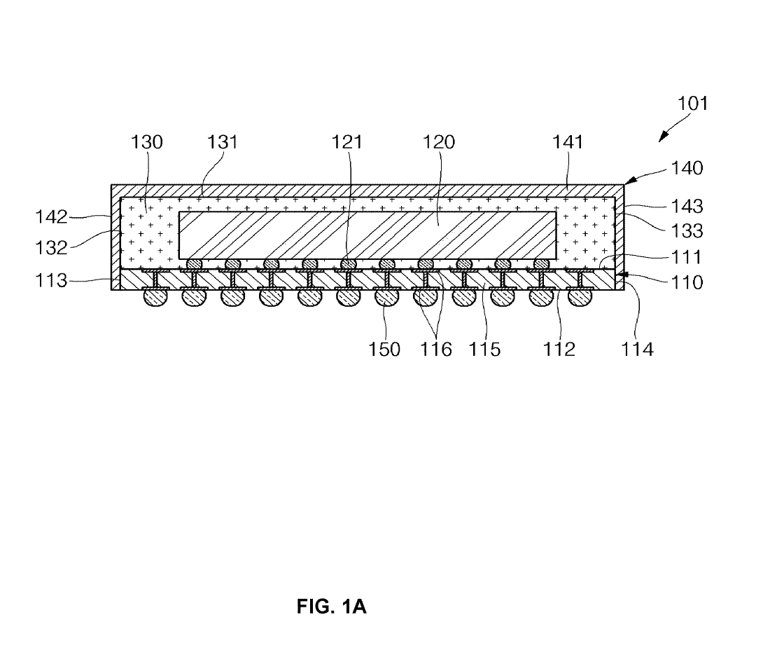

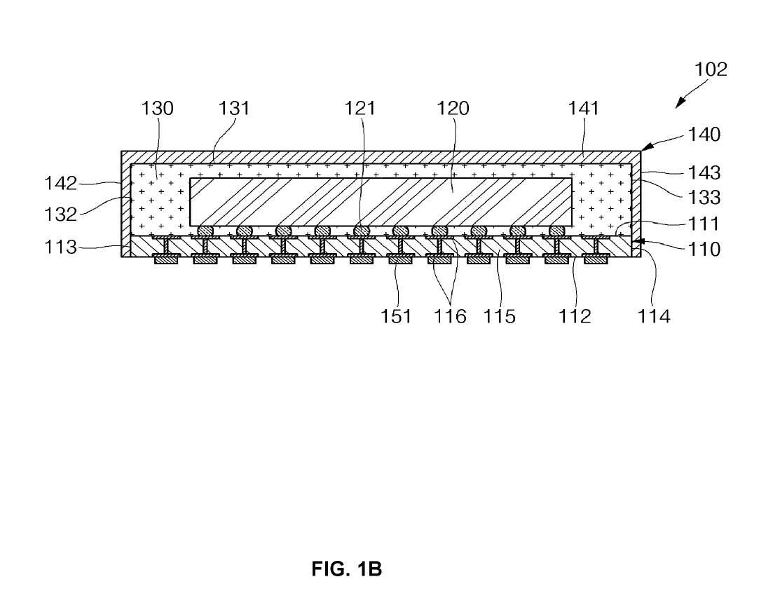

Referring to FIGS. 1A and 1B cross-sectional views illustrating semiconductor devices 101 and 102 according to embodiments of the present disclosure are illustrated.

As illustrated in FIGS. 1A and 1B, each of the semiconductor devices 101 and 102 according to embodiments of the present disclosure comprises a substrate 110, a semiconductor die 120, a molding portion 130, and an electromagnetic interference (EMI) shield layer 140. In addition, the semiconductor devices 101 and 102 according to embodiments of the present disclosure may comprise conductive bumps 150 and 151, respectively.

The substrate 110 may have a substantially planar top surface 111, a substantially planar bottom surface 112 opposite to the top surface 111, and four side surfaces 113 and 114 formed between the top surface 111 and the bottom surface 112. The substrate 110 may comprise a plurality of circuit patterns 116 formed inside and/or on a surface of an insulating body 115. The substrate 110 may provide an electrical signal path between the semiconductor die 120 and an external device while providing mechanical support for the semiconductor die 120.

The substrate 110 may comprise one of a rigid printed circuit board, a flexible printed circuit board, a ceramic circuit board, an interposer, and similar structures. A rigid printed circuit board may be configured such that a plurality of circuit patterns may be formed on its surface and/or inside using a phenol resin or an epoxy resin as a primary material. A flexible printed circuit board may be configured such that a plurality of circuit patterns may be formed on its surface and/or inside using a polyimide resin as a primary material. A ceramic circuit board may be configured such that a plurality of circuit patterns are formed on its surface and/or inside using a ceramic material as a primary material. An interposer may comprise a silicon based interposer or a dielectric material based interposer. Additionally, various types of substrates may be used in the present disclosure without limitation.

The semiconductor die 120 may be electrically connected to the circuit patterns 116 of the substrate 110. The semiconductor die 120 may be electrically connected to the circuit patterns 116 of the substrate 110 by, for example, micro bumps 121, or may be electrically connected to the circuit patterns 116 of the substrate 110 by conductive wires (not shown). The semiconductor die 120 may be electrically connected to the circuit patterns 116 of the substrate 110 by, for example, a mass reflow process, a thermal compression process or a laser bonding process. The semiconductor die 120 may comprise a plurality of semiconductor die in a horizontal direction and/or a vertical direction.

Moreover, the semiconductor die 120 may comprise integrated circuit chips separated from a semiconductor wafer. In addition, the semiconductor die 120 may comprise, for example, electrical circuits, such as central processing units (CPUs), digital signal processors (DSPs), network processors, power management units, audio processors, RF circuits, wireless baseband system on chip (SoC) processors, sensors and application specific integrated circuits.

The micro bumps 121 of the semiconductor die 120 may be used to electrically couple to conductive balls, such as solder balls, conductive pillars, such as copper pillars, and/or conductive posts each having a solder cap formed on a copper pillar.

The molding portion 130 may encapsulate the semiconductor die 120 on the substrate 110, thereby protecting the semiconductor die 120 against external mechanical/electrical/chemical contamination or shock. The molding portion 130 may comprise a planar top surface 131 and four side surfaces 132 and 133 extending from the top surface 131 to the substrate 110 in a substantially perpendicular direction. In an example scenario, the four side surfaces 132 and 133 formed on the molding portion 130 may be coplanar with the four side surfaces 113 and 114 of the substrate 110.

If a filler among various components of the molding portion 130 is smaller in size than a gap between the semiconductor die 120 and the substrate 110, the filler may fill the space between the semiconductor die 120 and the substrate 110, which is referred to as a molded underfill. In some cases, an underfill (not shown) may first be filled in the gap between the semiconductor die 120 and the substrate 110.

In addition, the molding portion 130 may comprise, for example, an encapsulant, such as an epoxy molding compound or an epoxy resin molding compound. The molding portion 130 may be formed by transfer molding, compression molding or injection molding, for example. However, the present disclosure does not limit the material of the molding portion 130 and the method for forming the molding portion 130 to those disclosed herein.

In addition, when a relatively rigid semiconductor device is utilized, a material having a relatively high modulus may be used as the material of the molding portion 130. When a relatively flexible semiconductor device is utilized, a material having a relatively low modulus may be used as the material of the molding portion 130.

The electromagnetic interference (EMI) shield layer 140 may cover or surround the substrate 110 and the molding portion 130, thereby preventing EMI from impinging on the semiconductor devices. The EMI shield layer 140 may comprise a first region 141 covering the top surface 131 of the molding portion 130, a second region 142 covering the side surfaces 132 and 113 of the molding portion 130 and the substrate 110, and a third region 143 covering the other side surfaces 133 and 114 of the molding portion 130 and the substrate 110.

The second and third regions 142 and 143 of the EMI shield layer 140 may entirely cover the four side surfaces 132 and 133 of the molding portion 130 and the four side surfaces 113 and 114 of the substrate 110. In other words, since only opposite side surfaces 132 and 133 of the molding portion 130 and opposite side surfaces 113 and 114 of the substrate 110 are illustrated in FIG. 1A, only the second and third regions 142 and 143 of the EMI shield layer 140 are illustrated. The EMI shield layer 140 may further comprise fourth and fifth regions covering the remaining opposite side surfaces of the molding portion 130 and the substrate 110.

As described above, the first region 141 of the EMI shield layer 140 may be substantially perpendicular to the second and third regions 142 and 143, and the second and third regions 142 and 143 of the EMI shield layer 140 may be parallel with each other.

Additionally, in some cases, the EMI shield layer 140 may be electrically connected to ground circuit patterns among the circuit patterns 116 formed on the substrate 110. Therefore, a ground signal of the semiconductor device may be further stabilized by the EMI shield layer 140.

The EMI shield layer 140 may comprise one or more of: silver (Ag), copper (Cu), aluminum (Al), nickel (Ni), palladium (Pd), chromium (Cr) and similar materials, but aspects of the present disclosure are not limited thereto. Additionally, the EMI shield layer 140 may be formed to a thickness of approximately 0.1 μm to approximately 20 μm but aspects of the present disclosure are not limited thereto. That is to say, the thickness of the EMI shield layer 140 may vary according to the characteristic or type of semiconductor device, in particular, the material and/or the number of layers of semiconductor device.

Contacts may be formed on the bottom surface 112 of the substrate 110. In the example of FIG. 1A, the contacts may comprise the conductive bumps 150, and in the example of FIG. 1B, the contacts may comprise conductive lands 151. The conductive bumps 150 may be electrically connected to the circuit patterns 116 formed on the bottom surface 112 of the substrate 110. As illustrated in FIG. 1A, the conductive bumps 150 may be formed in a ball type or a semicircular type. In this case, the semiconductor device 101 may be defined as a ball grid array package. In addition, as illustrated in FIG. 1B, the contacts 151 may comprise a conductive land or a rectangular type. In this case, the semiconductor device 102 may be defined as a land grid array package. The land grid array package may have a smaller thickness or height than the ball grid array package.

The conductive bumps 150 may comprise one or more of: a eutectic solder (Sn₃₇Pb), a high lead solder (Sn₉₅Pb), a lead-free solder (SnAg, SnAu, SnCu, SnZn, SnZnBi, SnAgCu, or SnAgBi), and similar materials, but aspects of the present disclosure are not limited thereto.

As described above, in the semiconductor devices 101 and 102 according to various embodiments of the present disclosure, EMI can be efficiently prevented from affecting the semiconductor devices 101 and 102 since the EMI shield layer 140 completely surrounds the top surface 131 and the four side surfaces 132 and 133 of the molding portion 130 and the four side surfaces 113 and 114 of the substrate 110.

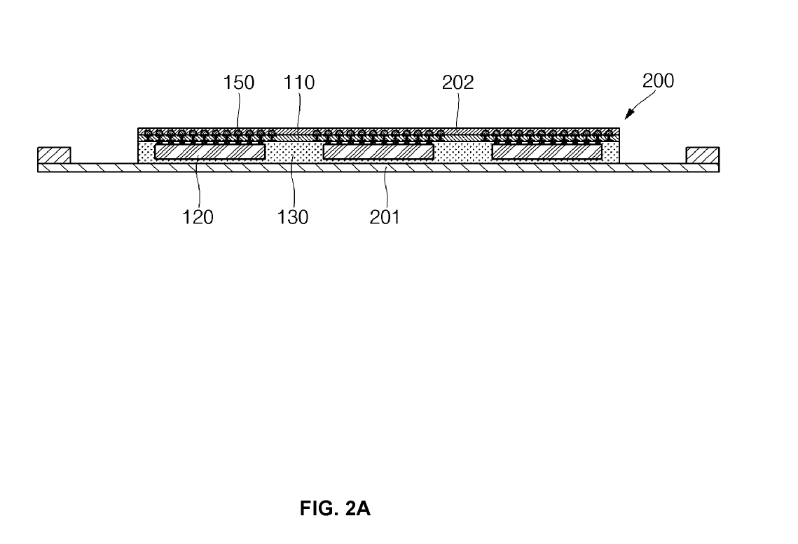

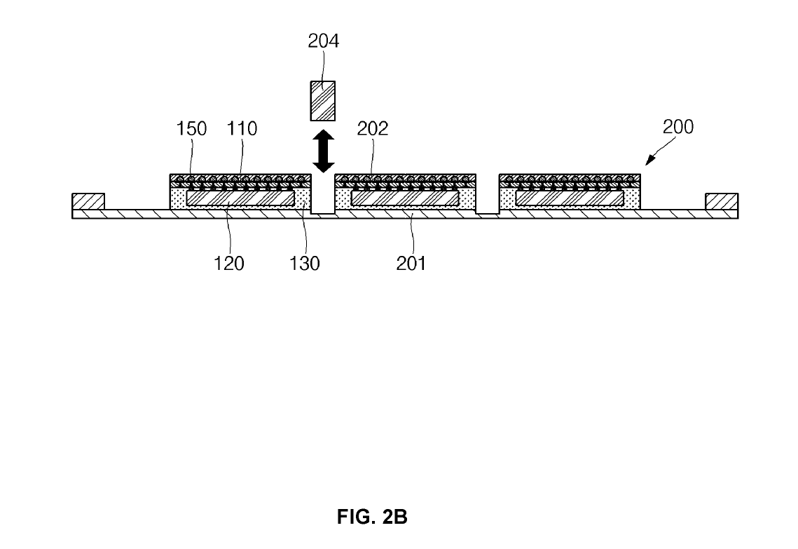

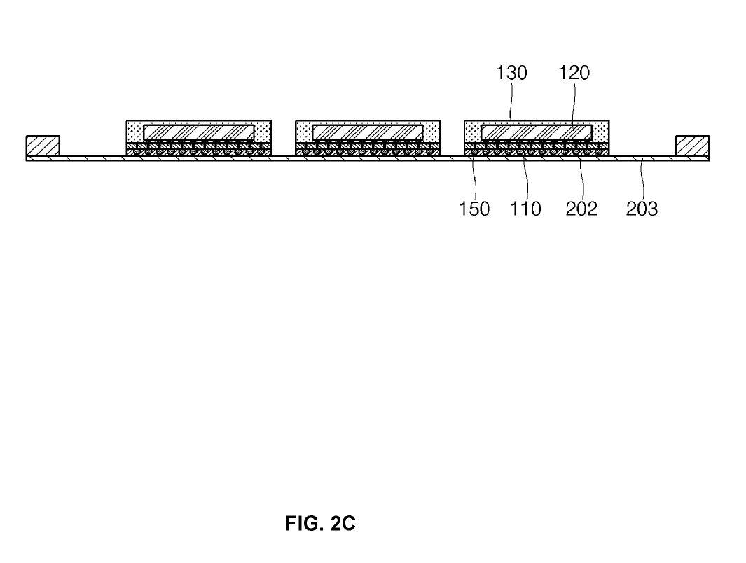

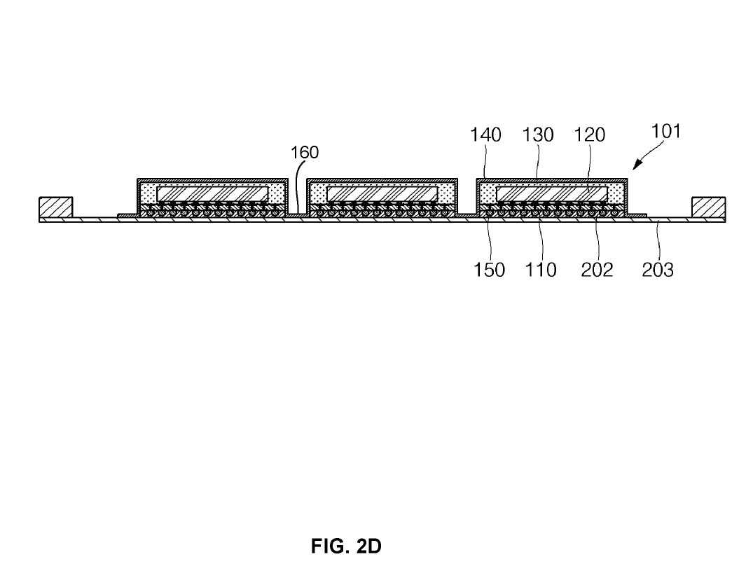

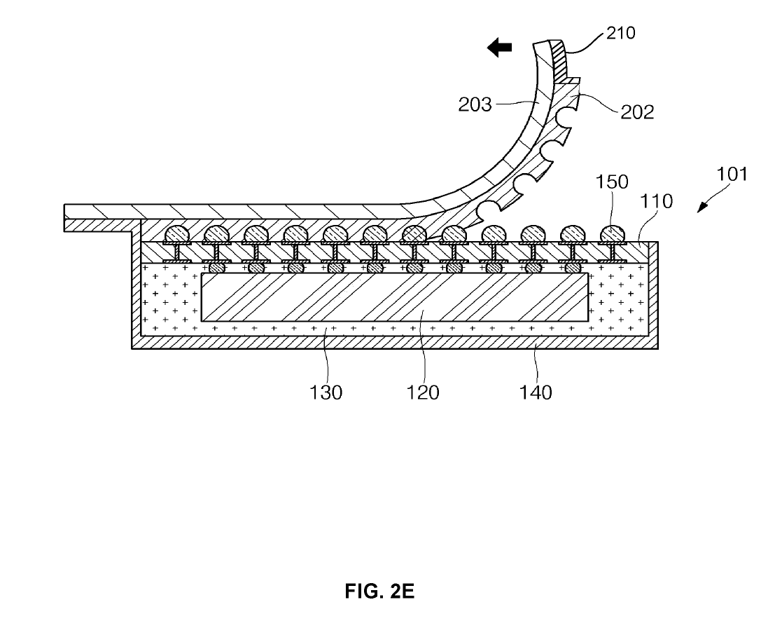

Referring to FIGS. 2A to 2E, cross-sectional views sequentially illustrating a method of manufacturing a semiconductor device 101 according to an embodiment of the present disclosure are illustrated.

The method of manufacturing the semiconductor device 101 according to an embodiment of the present disclosure includes attaching a semiconductor device group 200 onto a first adhesive tape 201, sawing, attaching individual semiconductor devices 101 onto a second adhesive tape 203, forming an EMI shield layer 140, and separating individual semiconductor devices 101 from the second adhesive tape 203.

As illustrated in FIG. 2A, the semiconductor device group 200 may be attached onto the first adhesive tape 201, with the device group 200 comprising a substrate 110, three semiconductor die 120, and a molding portion 130.

The molding portion 130 of the semiconductor device group 200 may be attached onto the first adhesive tape 201. In FIG. 2A, the semiconductor device group 200 comprises three semiconductor device units is illustrated, but the present disclosure does not limit the number of semiconductor device units to three. For example, the semiconductor device group 200 may any number of semiconductor device units depending on chip size and/or system complexity, for example.

The semiconductor device group 200 may comprise conductive bumps 150 formed on the substrate 110, which may be covered by a temporary adhesive layer 202. Therefore, since the temporary adhesive layer 202 completely covers and surrounds the conductive bumps 150, the conductive bumps 150 are not be exposed. The temporary adhesive layer 202 may be formed by one selected from laminating, coating, screen printing and similar processes, but aspects of the present disclosure are not limited thereto. Moreover, the conductive bumps 150 may be used to contact balls or lands.

The temporary adhesive layer 202 may include a high heat resistant base film made of, for example, polyimide (PI) or polyethylene naphthalate (PEN), an acryl- or silicone-based adhesive layer, which is adhered to the substrate 110. The temporary adhesive layer may have adhesiveness reduced by UV ray and/or heat, and/or which is curable by UV ray and/or heat to reinforce heat resistance. An intermediate layer may surround the conductive bumps 150 or fill gaps between the conductive bumps 150. The intermediate layer may also be an acryl- or silicone-based intermediate layer, which has adhesiveness lowered by UV ray and/or heat, and/or which is curable by UV ray and/or heat to prevent deformation or to reinforce heat resistance.

The adhesive layer and the intermediate layer may be integrally formed or may comprise multiple layers. The temporary adhesive layer 202 is illustrated in FIG. 2A comprising a single layer, but aspects of the present disclosure are not limited thereto. In another example scenario, the temporary adhesive layer 202 comprises a three-layered structure comprising a base film, an adhesive layer and an intermediate layer stacked in a top-to-bottom direction. In this example scenario, a top surface of the temporary adhesive layer 202 corresponds to the base film that is not adhesive.

The temporary adhesive layer 202 may comprise the following physical and chemical features. First, since a sputtering process may be performed at a temperature of approximately 100° C. to approximately 180° C. under a vacuum condition, the temporary adhesive layer 202 may exhibit heat resistance so as to withstand a high temperature without fumes, deformation, separation, or burning. Accordingly, as described above, a high heat resistant film made of PI or PEN may be suitably used as the base film. In addition, an acryl- or silicone-based high heat resistant adhesive may be used as the adhesive layer. However, if a shield layer is formed using a low-temperature process, heat resistance may not be a needed feature.

Second, the temporary adhesive layer 202 should be easily adhered or released in that the temporary adhesive layer 202 should maintain its adhesiveness with respect to rear surfaces 112, 150 and 151 of the substrate 110 even during sawing or sputtering. If the EMI shield layer 140 is formed by sputtering, the temporary adhesive layer 202 should be completely released without residuals. Third, the temporary adhesive layer 202 should surround the conductive bumps 150 well enough to prevent the conductive bumps 150 from being deformed.

The EMI shield layer 140 may comprise one or more of: silver (Ag), copper (Cu), aluminum (Al), nickel (Ni), palladium (Pd), chromium (Cr) and similar materials, but aspects of the present disclosure are not limited thereto. Additionally, the EMI shield layer 140 may be formed to a thickness of approximately 0.1 μm to approximately 20 μm but aspects of the present disclosure are not limited thereto. Accordingly, the thickness of the EMI shield layer 140 may vary according to the characteristic or type of semiconductor device, in particular, the material and/or the number of layers of semiconductor device.

In order to possess these features, the temporary adhesive layer 202 may include multiple layers. For example, as described above, the temporary adhesive layer 202 may comprise an adhesive layer to be adhered to the substrate, an intermediate layer surrounding the conductive bumps, and a base film. Fourth, the temporary adhesive layer 202 may have chemical resistance so as not to react with the EMI shield layer 140. Therefore, when the EMI shield layer 140 is formed by plating or spraying, rather than sputtering, the temporary adhesive layer 202 should not be deformed by being dissolved in or reacting with a solvent contained in a plating solution or a spraying solution. As described above, the temporary adhesive layer 202 having the aforementioned features may comprise an acryl- or silicone-based material, or other similar materials.

Optionally, in order to easily recognize a fiducial mark in a sawing process, the temporary adhesive layer 202 may be transparent. Accordingly, the temporary adhesive layer 202 may have a transmittance of, for example, approximately 60% to 90%, with respect to visible light or ultraviolet (UV) light. As described above, since the fiducial mark formed on a substrate, interposer, or circuit board may be easily identified by sawing equipment during the sawing process, the sawing process may be more accurately performed to separate into individual semiconductor devices.

As illustrated in FIG. 2B, sawing may be performed on the substrate 110 and the molding portion 130 constituting the semiconductor device group 200. In this step, the temporary adhesive layer 202 is also subjected to sawing. In the sawing process, the semiconductor device group 200 may be separated into multiple semiconductor devices. The sawing may be implemented by a general diamond blade 204 or laser beam, for example, but aspects of the present disclosure are not limited thereto. As a result of the sawing, the side surfaces of the substrate 110, the molding portion 130 and the temporary adhesive layer 202 may become coplanar.

As illustrated in FIG. 2C, the individual semiconductor devices may be attached such that the temporary adhesive layer 202 is attached onto the second adhesive tape 203. Since the individual semiconductor devices may be spaced a predetermined distance apart from each other and the temporary adhesive layer 202 may be attached to the underlying second adhesive tape 203, the molding portion 130 may face upward.

As illustrated in FIG. 2D, the EMI shield layer 140 may be formed on the individual semiconductor devices 101 attached onto the second adhesive tape 203. The EMI shield layer 140 may be formed by a process selected from sputtering, spraying, coating, electroless plating, electroplating and similar processes, or a combination thereof, but aspects of the present disclosure are not limited thereto.

The EMI shield layer 140 may be formed on the top surface 131 of the molding portion 130, opposite side surfaces 132 and 133 facing each other, i.e., four surfaces of the molding portion 130, opposite side surfaces 113 and 114 facing each other, i.e., four surfaces of the substrate 110, and opposite side surfaces facing each other, i.e., four surfaces of the temporary adhesive layer 202.

The EMI shield layer 140 may be formed on the facing side surfaces of the temporary adhesive layer 202 positioned under the substrate 110. The EMI shield layer 140 may also be formed on the second adhesive tape 203 corresponding to a gap 160 between the individual semiconductor devices 101 spaced apart from each other.

As illustrated in FIG. 2E, in separating the individual semiconductor devices 101 from the second adhesive tape 203 (or in the separating of the second adhesive tape 203 from the individual semiconductor devices 101), the second adhesive tape 203 and the temporary adhesive layer 202 may be peeled from the individual semiconductor devices 101 using a tool for pulling the tape, such as pliers (not shown). In this manner, the substrate 110 and the temporary adhesive layer 202 and the second adhesive tape 203 covering the conductive bumps 150 formed on the substrate 110 may be forcibly peeled away using the pliers, thereby exposing the conductive bumps 150 of the substrate 110 to the outside and cutting the EMI shield layer 140 integrally formed on the side surfaces 113 and 114 of the substrate 110 and on the side surfaces of the temporary adhesive layer 202, leaving a portion 210 of the EMI shield layer 140 on the second adhesive tape 203. Since an adhesive force between the EMI shield layer 140 and the substrate 110 is larger than an adhesive force between the temporary adhesive layer 202 and the substrate 110, the EMI shield layer 140 attached to the side surfaces 113 and 114 of the substrate 110 is not separated from the side surfaces 113 and 114 of the substrate 110.

As described above, according to the present disclosure, EMI between semiconductor devices can be prevented by the EMI shield layer 140 completely covering the top surface 131 and the four side surfaces 132 and 133 of the molding portion 130 and the four side surfaces 113 and 114 of the substrate 110. In an example scenario, the temporary adhesive layer 202 may be formed on the bottom surface 112 of the substrate 110, the EMI shield layer 140 may be formed to extend from the molding portion 130 and the side surfaces 113 and 114 of the substrate 110 to the surface of the temporary adhesive layer 202 and the temporary adhesive layer 202 may then be removed, thereby providing the semiconductor device having the side surfaces 113 and 114 of the substrate 110 completely covered by the EMI shield layer 140.

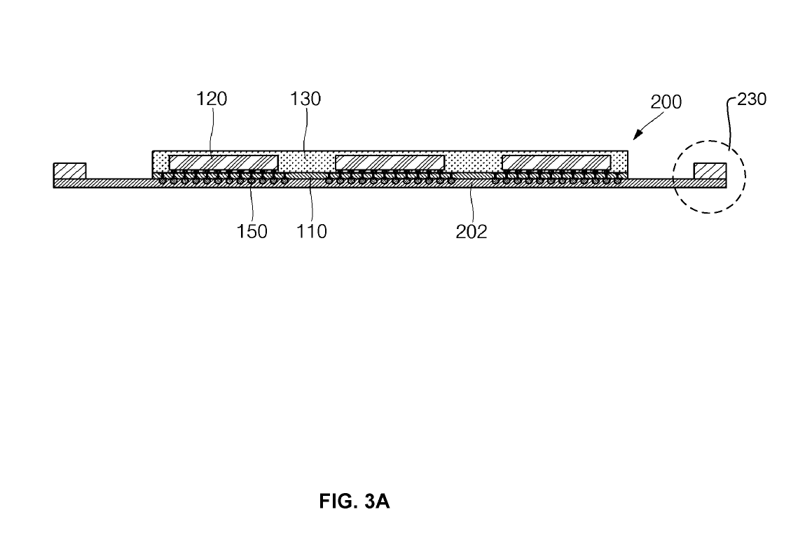

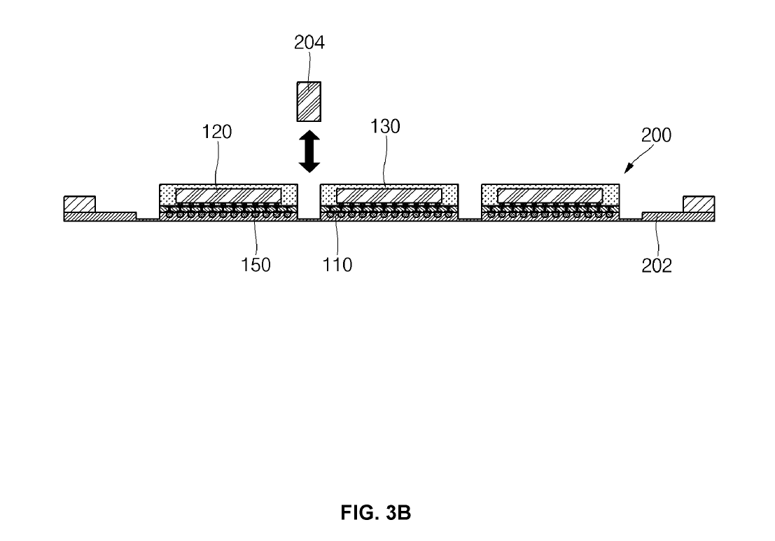

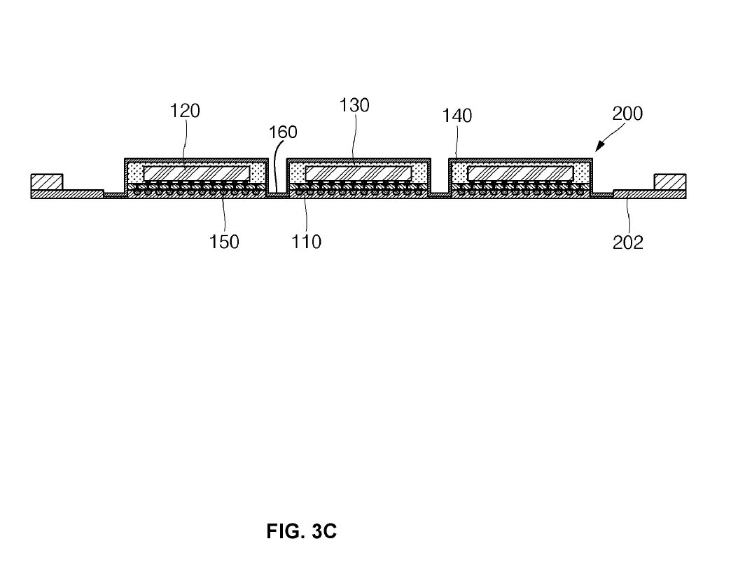

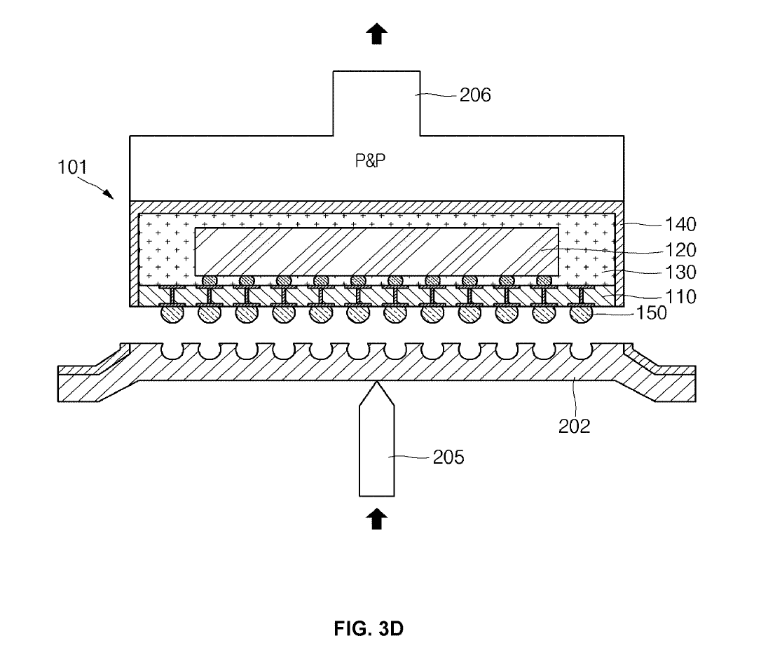

Referring to FIGS. 3A to 3D, cross-sectional views sequentially illustrating a method of manufacturing a semiconductor device according to another embodiment of the present disclosure are illustrated.

The method of manufacturing the semiconductor device 101 according to the embodiment of the present disclosure includes attaching a semiconductor device group 200 onto a temporary adhesive layer 202, sawing, forming an EMI shield layer 140, and separating individual semiconductor devices 101 from the temporary adhesive layer 202.

As illustrated in FIG. 3A, the semiconductor device group 200 comprising a substrate 110, three semiconductor die 120 and a molding portion 130 may be attached to the temporary adhesive layer 202. The conductive bumps 150 of the semiconductor device group 200 may be attached onto the temporary adhesive layer 202 and may be covered by the temporary adhesive layer 202. A bottom surface of the substrate 110 may be directly attached to the temporary adhesive layer 202. Accordingly, since the temporary adhesive layer 202 completely covers the conductive bumps 150, the conductive bumps 150 are not exposed to the outside.

The temporary adhesive layer 202 may be pre-attached to a ring frame 230 and compresses the semiconductor device group 200 in a state in which the conductive bumps 150 of the semiconductor device group 200 are positioned to face the temporary adhesive layer 202, thereby attaching the substrate 110 and the conductive bumps 150 to the temporary adhesive layer 202.

Additionally, since physical and chemical features of the temporary adhesive layer 202 may be similar to those described above, detailed descriptions thereof will not be given.

As illustrated in FIG. 3B, the substrate 110, the die 120, and molding portion 130 constituting the semiconductor device group 200 may be singulated in a sawing process. In this step, the temporary adhesive layer 202 may also be subjected to sawing. In the sawing process, the semiconductor device group 200 may be separated into multiple semiconductor devices. The sawing may be implemented by a general diamond blade 204 or laser beam, but aspects of the present disclosure are not limited thereto.

As illustrated in FIG. 3C, the EMI shield layer 140 may be formed on the individual semiconductor devices 101 attached to the temporary adhesive layer 202. The EMI shield layer 140 may formed on a top surface 131 of the molding portion 130, opposite side surfaces 132 and 133 facing each other, i.e., four surfaces of the molding portion 130, opposite side surfaces 113 and 114 facing each other, i.e., four side surfaces of the substrate 110, and opposite side surfaces facing each other, i.e., four side surfaces of the temporary adhesive layer 202.

The EMI shield layer 140 may be formed on the surfaces of the temporary adhesive layer 202 positioned under the substrate 110 and on the surface of the temporary adhesive layer 202 corresponding to a gap 160 between the individual semiconductor devices 101 spaced apart from each other.

As illustrated in FIG. 3D, the individual semiconductor devices 101 may be separated by picking up the individual semiconductor devices 101 from the temporary adhesive layer 202 using pick and place equipment 206, for example. Accordingly, after the temporary adhesive layer 202 is pushed slightly upward using a needle 205, the semiconductor devices 101 may be pulled upward, or picked, using the pick and place equipment 206, thereby separating the substrate 110 and the conductive bumps 150 from the temporary adhesive layer 202.

Since the adhesive force between the EMI shield layer 140 and the substrate 110 is larger than the adhesive force between the temporary adhesive layer 202 and the substrate 110, the EMI shield layer 140 is not separated from the side surfaces 113 and 114 of the substrate 110. Therefore, a portion of the EMI shield layer 140 remains attached to the side surfaces 113 and 114 of the substrate 110 and a portion of the EMI shield layer 140 remains attached to the temporary adhesive layer 202.

Since the bottom surface of the temporary adhesive layer 202 may comprise a base film without adhesiveness, the needle 205 does not attach to the base film of the temporary adhesive layer 202 nor become contaminated by it.

Although not shown, the separation of the individual semiconductor devices 101 and 102 may be performed by dissolving the temporary adhesive layer 202 in a chemical solution for removal, while the chemical solution does not react with the EMI shield layer 140.

As described above, according to the present disclosure, EMI between semiconductor devices can be prevented by the EMI shield layer 140 completely covering the top surface 131 and the four side surfaces 132 and 133 of the molding portion 130 and the four side surfaces 113 and 114 of the substrate 110. In particular, according to the present disclosure, the temporary adhesive layer 202 may be formed on the bottom surface 112 of the substrate 110. The EMI shield layer 140 may be formed to extend from the molding portion 130 and the side surfaces 113 and 114 of the substrate 110 to the side surfaces of the temporary adhesive layer 202. The semiconductor devices may then be removed from the temporary adhesive layer 202, thereby providing the semiconductor device having the side surfaces 113 and 114 of the substrate 110 completely covered by the EMI shield layer 140.

In an example embodiment of the disclosure, a semiconductor device with an electromagnetic interference (EMI) shield comprises a substrate comprising a first surface and a second surface opposite to the first surface, a semiconductor die coupled to the first surface of the substrate, an encapsulant encapsulating the semiconductor die and portions of the first surface of the substrate, and an electromagnetic interference (EMI) shield layer on the encapsulant and side surfaces of the substrate between the first and second surfaces. Contacts may be on the second surface of the substrate, where the contacts may comprise conductive bumps or conductive lands. The EMI shield layer may comprise one or more of silver, copper, aluminum, nickel, palladium, and chromium. The EMI shield layer may be coupled to a ground circuit pattern of the substrate.

In another example embodiment of the disclosure, a method of forming semiconductor device with an electromagnetic interference (EMI) shield comprises coupling a semiconductor die to a first surface of a substrate, encapsulating the semiconductor die and portions of the first surface of the substrate using an encapsulant, coupling electrical contacts to a second surface of the substrate opposite to the first surface of the substrate, and placing an adhesive layer on the second surface of the substrate such that the adhesive layer surrounds the electrical contacts. The encapsulated substrate and semiconductor die may be placed on an adhesive tape. An electromagnetic interference (EMI) shield layer may be formed on the encapsulant, on side surfaces of the substrate, and on portions of the adhesive tape adjacent to the encapsulated substrate and semiconductor die. The adhesive tape and the adhesive layer may be peeled away from the encapsulated substrate and semiconductor die thereby leaving portions of the EMI shield layer on the encapsulant and on the side surfaces of the substrate with other portions of the EMI shield layer remaining on portions of the adhesive tape that were adjacent to the encapsulated substrate and semiconductor die. The electrical contacts may comprise conductive bumps or conductive lands. The EMI shield layer may comprise one or more of silver, copper, aluminum, nickel, palladium, and chromium. The EMI shield layer may be coupled to a ground circuit pattern of the substrate. The adhesive layer may comprise a heat resistant base film comprising one of: polyimide (PI), polyethylene naphthalate (PEN), or a silicone-based adhesive layer.

While various aspects supporting the disclosure have been described with reference to certain example embodiments, it will be understood by those skilled in the art that various changes may be made and equivalents may be substituted without departing from the scope of the present disclosure. In addition, many modifications may be made to adapt a particular situation or material to the teachings of the present disclosure without departing from its scope. Therefore, it is intended that the present disclosure not be limited to the particular example embodiments disclosed, but that the present disclosure will include all embodiments falling within the scope of the appended claims.

What is claimed is:

1. A method of forming a semiconductor device, the method comprising:
coupling a semiconductor die to a first surface of a substrate;
encapsulating the semiconductor die and portions of the first surface of the substrate using an encapsulant;
placing the encapsulated substrate and semiconductor die on an adhesive tape;
forming an electromagnetic interference (EMI) shield layer on the encapsulant, on side surfaces of the substrate, and on portions of the adhesive tape adjacent to the encapsulated substrate and semiconductor die;
peeling away the adhesive tape from the encapsulated substrate and semiconductor die, thereby leaving portions of the EMI shield layer on the encapsulant and on the side surfaces of the substrate with other portions of the EMI shield layer remaining on portions of the adhesive tape that were adjacent to the encapsulated substrate and semiconductor die.

2. The method according to claim 1, comprising forming contacts on a second surface of the substrate opposite to the first surface of the substrate.

3. The method according to claim 2, wherein the contacts comprise conductive bumps.

4. The method according to claim 2, wherein the contacts comprise conductive lands.

5. The method according to claim 2, comprising placing an adhesive layer on the contacts and the second surface of the substrate, such that the contacts are encapsulated by the adhesive layer.

6. The method according to claim 5, wherein the adhesive layer is removed in the peeling away of the adhesive tape.

7. The method according to claim 1, wherein the EMI shield layer comprises one or more of: silver, copper, aluminum, nickel, palladium, and/or chromium.

8. The method according to claim 1, wherein the EMI shield layer is coupled to a ground circuit pattern of the substrate.

9. A semiconductor device comprising:
a substrate comprising a first surface and a second surface opposite to the first surface;
a semiconductor die coupled to the first surface of the substrate;
an encapsulant encapsulating the semiconductor die and portions of the first surface of the substrate; and
an electromagnetic interference (EMI) shield layer on the encapsulant and side surfaces of the substrate between the first and second surfaces.

10. The semiconductor device according to claim 9, comprising contacts on the second surface of the substrate.

11. The semiconductor device according to claim 10, wherein the contacts comprise conductive bumps.

12. The semiconductor device according to claim 10, wherein the contacts comprise conductive lands.

13. The semiconductor device according to claim 9, wherein the EMI shield layer comprises one or more of: silver, copper, aluminum, nickel, palladium, and/or chromium.

14. The semiconductor device according to claim 9, wherein the EMI shield layer is coupled to a ground circuit pattern of the substrate.

15. A method of fabricating a semiconductor device, the method comprising:
coupling a semiconductor die to a first surface of a substrate;
encapsulating the semiconductor die and portions of the first surface of the substrate using an encapsulant;
coupling electrical contacts to a second surface of the substrate opposite to the first surface of the substrate;
placing an adhesive layer on the second surface of the substrate such that the adhesive layer surrounds the electrical contacts;
placing the encapsulated substrate and semiconductor die on an adhesive tape;
forming an electromagnetic interference (EMI) shield layer on the encapsulant, on side surfaces of the substrate, and on portions of the adhesive tape adjacent to the encapsulated substrate and semiconductor die; and
peeling away the adhesive tape and the adhesive layer from the encapsulated substrate and semiconductor die, thereby leaving portions of the EMI shield layer on the encapsulant and on the side surfaces of the substrate with other portions of the EMI shield layer remaining on portions of the adhesive tape that were adjacent to the encapsulated substrate and semiconductor die.

16. The method according to claim 15, wherein the electrical contacts comprise conductive bumps.

17. The method according to claim 15, wherein the electrical contacts comprise conductive lands.

18. The method according to claim 15, wherein the EMI shield layer comprises one or more of silver, copper, aluminum, nickel, palladium, and chromium.

19. The method according to claim 15, wherein the EMI shield layer is coupled to a ground circuit pattern of the substrate.

20. The method according to claim 15, wherein the adhesive layer comprises a heat resistant base film comprising one or more of: polyimide (PI), polyethylene naphthalate (PEN), and/or a silicone-based adhesive layer.
